(19) United States
(12) Patent Application Publication
(10) Pub. No.: US 2006/0183284 A1
(43) Pub. Date: Aug. 17, 2006

(54) Non-volatile semiconductor storage device and the manufacturing method thereof

(75) Inventors: Yoshitaka Sasago, Tachikawa (JP); Tsuyoshi Arigane, Akishima (JP); Tetsufumi Kawamura, Kokubunji (JP); Hitoshi Kume, Musasino (JP); Takashi Kobayashi, Higashimurayama (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/316,817

(22) Filed: Dec. 27, 2005

(30) Foreign Application Priority Data
Jan. 28, 2005 (JP) 2005-021626

(51) Int. Cl. H01L 21/336

(52) U.S. Cl. 438/257; 438/264

(57) ABSTRACT

High integration and making a non-volatile semiconductor memory efficient have been promoted. The memory cell consists of a floating gate, a control gate constituting a word line WL and a MOS transistor having an assist gate. The thickness of the gate oxide film of the assist gate is thinner than the thickness of the gate oxide layer of the floating gate, and the dimensions of the assist gate (gate width) in the direction lying along the word line WL is smaller than the gate length of the floating gate in the direction lying along the word line WL. Moreover, the channel dopant concentration underneath the assist gate is lower than the channel dopant concentration underneath the floating gate.

### CLAIM OF PRIORITY

The present application claims priority from Japanese application JP 2005-021626 filed on Jan. 28, 2005, the content of which is hereby incorporated by reference into this application.

### FIELD OF THE INVENTION

The present invention relates to a non-volatile semiconductor storage device and a manufacturing method thereof, and more particularly to an effective technology applied to achieve high integration and high performance for non-volatile semiconductor storage devices which are capable of programming/erasing electrically.

### BACKGROUND OF THE INVENTION

A so-called flash memory is known as one for which bulk erasing is possible in non-volatile semiconductor memory devices, in which electric programming/erasing of data is possible. Because flash memory is easy to carry, has excellent shock resistance, and electric bulk erasing is possible, it has seen a rapidly increasing demand in these days as a memory device for personal digital assistants such as mobile personal computers and digital still cameras.

The most important market requirement of flash memory is a reduction in the bit cost and an increase in the writing speed. Up to now, in order to achieve a reduction in the bit cost, a so-called contactless flash memory technology, which does not have a contact hole from one memory cell to the next, has been used. As a result of efforts to decrease both the bit line pitch and the word line pitch, a bit line pitch=2 F and a word line pitch=2 F have been achieved when the pattern rule is assumed to be F (International Electron Devices Meeting, 2003, pp. 823-826; International Electron Devices Meeting, 2003, pp. 819-822; and 2003 Symposium on VLSI Technology pp. 89-90). In this case, the physical cell surface area becomes 4 F², but an area of 2 F² per bit can be achieved by applying a multilevel technology of 2 bits/cell as described in International Electron Devices Meeting, 2003, pp. 823-826 and 2003 Symposium on VLSI Technology pp. 89-90.

In an example of International Electron Devices Meeting, 2003, pp. 823-826, an increase in the writing speed which is yet another problem has been achieved by using source side hot electron injection for programming. Moreover, a Constant-Charge-Injectioh Programming (CCIP) described in 2002 Symposium on VLSI Circuits pp. 302-303 and a technique described in 2004 Symposium on VLSI Circuits pp. 72-73 which is applicable to a cell in International Electron Devices Meeting, 2003, pp. 823-826 have been developed as techniques to decrease the variability of the programming speed caused by the channel current distribution which becomes a problem while programming by the source side hot electron injection.

### SUMMARY OF THE INVENTION

In a method described in International Electron Devices Meeting, 2003, pp. 823-826 and 2004 Symposium on VLSI Circuits pp. 72-73 which are currently being used, a memory cell structure having a third gate in addition to a floating gate and a control gate is adopted, and an inversion layer formed by biasing a voltage to the third gate is used as a local bit line. Therefore, since the diffusion layer of the local bit line becomes unnecessary, it is possible to decrease the bit line pitch by 2 F.

However, the resistance of the local data line is increased because an inversion layer is hardly formed underneath the third gate due to a so-called narrow-channel effect when the reduction in the memory cell size progresses further. And so, an increase in the resistance of the local data line causes problems as follows.

(1) The effect of a source side hot electron injection is decreased because the drain voltage is decreased in the memory cell part while programming.

(2) The reading speed is decreased because the reading current is decreased.

Moreover, a decrease in the distance between the adjacent memory cells increases the electrostatic capacitance between the floating gates. Therefore, the threshold voltage shift that a shift of the voltage of a cell (state of the threshold voltage) gives to an adjacent cell cannot be ignored, so that a problem, such as a miss-read, etc., arises in which reliability of the memory cell is deteriorated.

It is an object of the present invention to provide a technology which advances the high integration and high performance of a non-volatile semiconductor storage device.

The aforementioned and other objects and new features of the present invention will be more clearly understood from the following description and accompanying drawings of these detailed descriptions.

The following is a brief description of a typical embodiment disclosed in the present invention.

According to the present invention, a non-volatile semiconductor storage device comprises a plurality of first gates formed on the main surface of a semiconductor substrate through a first insulator film, a plurality of second gates electrically separated from the first gate through a second insulator film covering the first gate and lying in a first direction of the main surface of the semiconductor substrate, and a plurality of third gates formed on the main surface of the semiconductor substrate through a third insulator film, electrically separated from the first gate through a fourth insulator film, electrically separated from said second film through the second insulator film and lying in a second direction intersecting said first direction. In a non-volatile semiconductor storage device which uses an inversion layer formed on the surface of the semiconductor substrate underneath the third gate for a local data line when a voltage is biased to the third gate, the dimension of the third gate in the first direction on the third insulator film is made 10% or more greater than the dimension of the first gate in the first direction on the first insulator film.

The following is a brief description of a typical embodiment disclosed in the present invention.

It is possible to control the increase in the resistance of the local bit line which becomes noticeable attendant with a reduction in the bit line pitch of a semiconductor storage device, in which an inversion layer is used for a local bit line.

It is possible to decrease the threshold voltage shift of a memory cell due to the capacitive coupling between adjacent floating gates, which becomes noticeable attendant with a decrease in the word line pitch.

### BRIEF DESCRIPTION OF THE DRAWINGS

FIG. 1 is a plane diagram schematically illustrating a memory cell of a flash memory of one embodiment of the present invention.

FIG. 2A is a cross-sectional drawing at the position of line A-A′ in FIG. 1.

FIG. 2B is a cross-sectional drawing at the position of line B-B′ in FIG. 1.

FIG. 2C is a cross-sectional drawing at the position of line C-C′ in FIG. 1.

FIG. 3 is a circuit drawing of a memory array showing the voltage conditions while reading a flash memory of one embodiment of the present invention.

FIG. 4 is a circuit drawing of a memory array showing the voltage conditions while programming a flash memory of one embodiment of the present invention.

FIG. 5 is a circuit drawing of a memory array explaining a programming operation of a flash memory of one embodiment of the present invention.

FIG. 6 is a circuit drawing of a memory array explaining a programming operation of a flash memory of one embodiment of the present invention.

FIG. 7 is a circuit drawing of a memory array explaining a programming operation of a flash memory of one embodiment of the present invention.

FIG. 8 is a circuit drawing of a memory array explaining a programming operation of a flash memory of one embodiment of the present invention.

FIG. 9A is a main cross-sectional drawing of a semiconductor substrate illustrating a manufacturing method of a flash memory described in one embodiment of the present invention.

FIG. 9B is a main cross-sectional drawing of a semiconductor substrate illustrating a manufacturing method of a flash memory described in one embodiment of the present invention.

FIG. 9C is a main cross-sectional drawing of a semiconductor substrate illustrating a manufacturing method of a flash memory described in one embodiment of the present invention.

FIG. 10A is a main cross-sectional drawing of a semiconductor substrate illustrating a manufacturing method following FIG. 9 of a flash memory described in one embodiment of the present invention.

FIG. 10B is a main cross-sectional drawing of a semiconductor substrate illustrating a manufacturing method following FIG. 9 of a flash memory described in one embodiment of the present invention.

FIG. 10C is a main cross-sectional drawing of a semiconductor substrate illustrating a manufacturing method following FIG. 9 of a flash memory described in one embodiment of the present invention.

FIG. 11A is a main cross-sectional drawing of a semiconductor substrate illustrating a manufacturing method following FIG. 10 of a flash memory described in one embodiment of the present invention.

FIG. 11B is a main cross-sectional drawing of a semiconductor substrate illustrating a manufacturing method following FIG. 10 of a flash memory described in one embodiment of the present invention.

FIG. 11C is a main cross-sectional drawing of a semiconductor substrate illustrating a manufacturing method following FIG. 10 of a flash memory described in one embodiment of the present invention.

FIG. 12A is a main cross-sectional drawing of a semiconductor substrate illustrating a manufacturing method following FIG. 11 of a flash memory described in one embodiment of the present invention.

FIG. 12B is a main cross-sectional drawing of a semiconductor substrate illustrating a manufacturing method following FIG. 11 of a flash memory described in one embodiment of the present invention.

FIG. 12C is a main cross-sectional drawing of a semiconductor substrate illustrating a manufacturing method following FIG. 11 of a flash memory described in one embodiment of the present invention.

FIG. 13A is a main cross-sectional drawing of a semiconductor substrate illustrating a manufacturing method following FIG. 12 of a flash memory described in one embodiment of the present invention.

FIG. 13B is a main cross-sectional drawing of a semiconductor substrate illustrating a manufacturing method following FIG. 12 of a flash memory described in one embodiment of the present invention.

FIG. 14A is a main cross-sectional drawing of a semiconductor substrate illustrating a manufacturing method following FIG. 13 of a flash memory described in one embodiment of the present invention.

FIG. 14B is a main cross-sectional drawing of a semiconductor substrate illustrating a manufacturing method following FIG. 13 of a flash memory described in one embodiment of the present invention.

FIG. 15A is a main cross-sectional drawing of a semiconductor substrate illustrating a manufacturing method following FIG. 14 of a flash memory described in one embodiment of the present invention.

FIG. 15B is a main cross-sectional drawing of a semiconductor substrate illustrating a manufacturing method following FIG. 14 of a flash memory described in one embodiment of the present invention.

FIG. 15C is a main cross-sectional drawing of a semiconductor substrate illustrating a manufacturing method following FIG. 14 of a flash memory described in one embodiment of the present invention.

FIG. 16A is a main cross-sectional drawing of a semiconductor substrate illustrating a manufacturing method following FIG. 15 of a flash memory described in one embodiment of the present invention.

FIG. 16B is a main cross-sectional drawing of a semiconductor substrate illustrating a manufacturing method following FIG. 15 of a flash memory described in one embodiment of the present invention.

FIG. 16C is a main cross-sectional drawing of a semiconductor substrate illustrating a manufacturing method following FIG. 15 of a flash memory described in one embodiment of the present invention.

FIG. 17 is a main plane drawing of a semiconductor substrate illustrating a manufacturing method following FIG. 16 of a flash memory.

FIG. 18A is a main cross-sectional drawing of a semiconductor substrate illustrating a manufacturing method following FIG. 16 of a flash memory described in one embodiment of the present invention.

FIG. 18B is a main cross-sectional drawing of a semiconductor substrate illustrating a manufacturing method following FIG. 16 of a flash memory described in one embodiment of the present invention.

FIG. 18C is a main cross-sectional drawing of a semiconductor substrate illustrating a manufacturing method following FIG. 16 of a flash memory described in one embodiment of the present invention.

FIG. 19A is a schematic drawing illustrating the corresponding part of a gate oxide film capacitance (Cox) and a depletion layer capacitance (Cdep) of an assist gate.

FIG. 19B is a graph illustrating a relationship between the gate width of an assist gate and the boost voltage.

FIG. 20 is a graph illustrating a relationship between the gate width of an assist gate and the resistance of an inversion layer.

FIG. 21 is a graph illustrating a relationship between the gate length of a floating gate and the amount of the threshold voltage shift.

FIG. 22A is a main cross-sectional drawing of a semiconductor substrate illustrating a manufacturing method of a flash memory described in another embodiment of the present invention.

FIG. 22B is a main cross-sectional drawing of a semiconductor substrate illustrating a manufacturing method of a flash memory described in another embodiment of the present invention.

FIG. 22C is a main cross-sectional drawing of a semiconductor substrate illustrating a manufacturing method of a flash memory described in another embodiment of the present invention.

FIG. 23A is a main cross-sectional drawing of a semiconductor substrate illustrating a manufacturing method following FIG. 22 of a flash memory.

FIG. 23B is a main cross-sectional drawing of a semiconductor substrate illustrating a manufacturing method following FIG. 22 of a flash memory.

FIG. 23C is a main cross-sectional drawing of a semiconductor substrate illustrating a manufacturing method following FIG. 22 of a flash memory.

FIG. 24A is a main cross-sectional drawing of a semiconductor substrate illustrating a manufacturing method following FIG. 23 of a flash memory.

FIG. 24B is a main cross-sectional drawing of a semiconductor substrate illustrating a manufacturing method following FIG. 23 of a flash memory.

FIG. 24C is a main cross-sectional drawing of a semiconductor substrate illustrating a manufacturing method following FIG. 23 of a flash memory.

FIG. 25A is a main cross-sectional drawing of a semiconductor substrate illustrating a manufacturing method following FIG. 24 of a flash memory.

FIG. 25B is a main cross-sectional drawing of a semiconductor substrate illustrating a manufacturing method following FIG. 24 of a flash memory.

FIG. 25C is a main cross-sectional drawing of a semiconductor substrate illustrating a manufacturing method following FIG. 24 of a flash memory.

FIG. 26A is a main cross-sectional drawing of a semiconductor substrate illustrating a manufacturing method following FIG. 25 of a flash memory.

FIG. 26B is a main cross-sectional drawing of a semiconductor substrate illustrating a manufacturing method following FIG. 25 of a flash memory.

FIG. 26C is a main cross-sectional drawing of a semiconductor substrate illustrating a manufacturing method following FIG. 25 of a flash memory.

FIG. 27A is a main cross-sectional drawing of a semiconductor substrate illustrating a manufacturing method following FIG. 26 of a flash memory.

FIG. 27B is a main cross-sectional drawing of a semiconductor substrate illustrating a manufacturing method following FIG. 26 of a flash memory.

FIG. 27C is a main cross-sectional drawing of a semiconductor substrate illustrating a manufacturing method following FIG. 26 of a flash memory.

FIG. 28A is a main cross-sectional drawing of a semiconductor substrate illustrating a manufacturing method of a flash memory described in another embodiment of the present invention.

FIG. 28B is a main cross-sectional drawing of a semiconductor substrate illustrating a manufacturing method of a flash memory described in another embodiment of the present invention.

FIG. 28C is a main cross-sectional drawing of a semiconductor substrate illustrating a manufacturing method of a flash memory described in another embodiment of the present invention.

FIG. 29 is a graph where the relationship of the gate width to the leakage current between the source and the drain in each of the memory cells of each embodiment.

### DETAILED DESCRIPTION OF THE PREFERRED DRAWINGS

The following is a detailed description of the embodiments of the present invention with reference to the accompanying drawings. In all the drawings used to describe the embodiments, like reference characters designate corresponding parts in several drawings and the repetition of the description is omitted.

### First Embodiment

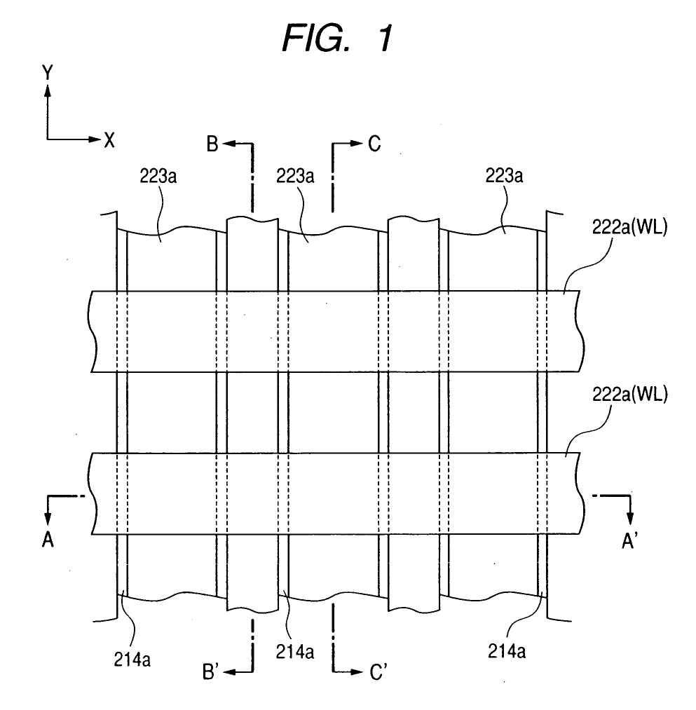

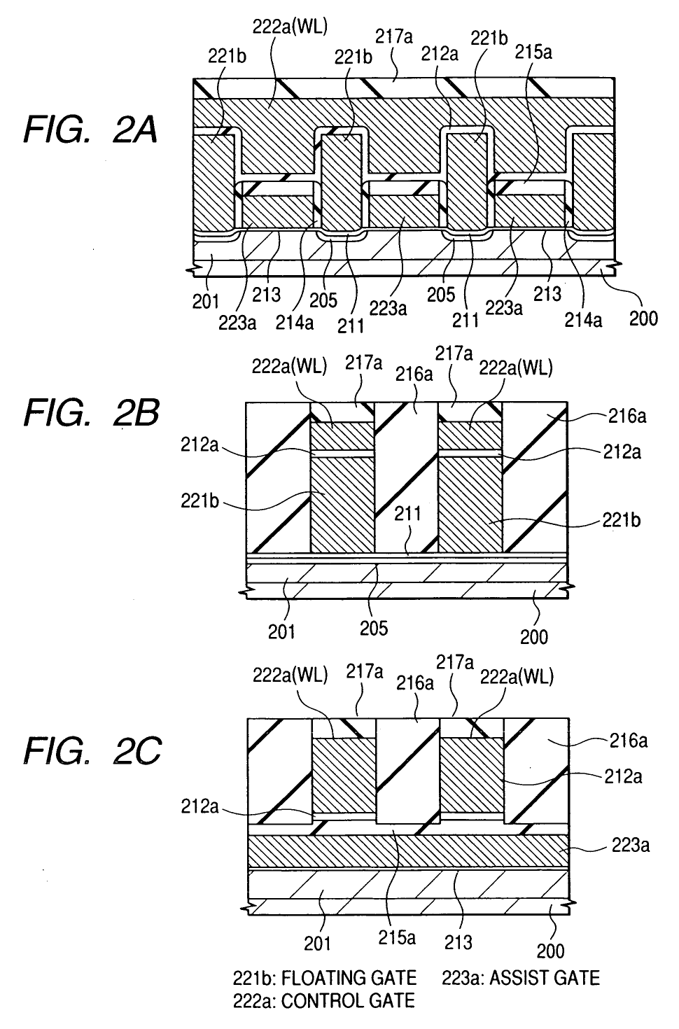

FIG. 1 is a plane drawing illustrating one example of a memory cell of a flash memory described in this embodiment. FIGS. 2A, 2B, and 2C are cross-sectional views at the position of line A-A′, line B-B′, and line C-C′ of FIG. 1, respectively. In FIG. 1, a part of the material section has been omitted to make the diagram easy to see.

The non-volatile semiconductor storage device described in this embodiment has a memory cell of a so-called flash memory. This memory cell comprises a p-well 201 formed on the main surface of a semiconductor substrate 200 (hereinafter, it is called a substrate), a floating gate (first gate) 221b, a control gate (second gate) 222a, and an assist gate (third gate) 223a.

The control gate 222a of each memory cell is connected in the line direction (x direction) shown in FIG. 1 to form the word line WL. The floating gate 221b and p-well 201 are separated by the gate oxide film (first insulator film) 211 and the floating gate 221b and the assist gate 223a are separated by a silicon oxide film (fourth insulator film) 214a. Moreover, the floating gate 221b and the control gate 222a (word line WL) are separated by an insulator film (second insulator film) 212a. Both floating gates 221b which are adjacent to each other in a direction perpendicular to the word line WL are separated by a silicon oxide film (sixth insulator film) 216a. Furthermore, the assist gate 223a and the control gate 222a (word line WL) are separated by a silicon nitride film 215a (fifth insulator film) and the insulator film 212a, and the assist gate 223a and p-well 201 are separated by the gate oxide film (third insulator film) 213.

The source and drain of the memory cell consist of an inversion layer, which is formed in the p-well 201 underneath the assist gate 223a by biasing a voltage to the assist gate 223a lying in the line direction (y direction) perpendicular to the row direction (x direction), and they function as a local data line. That is, the flash memory device described in this embodiment consists of a so-called contactless array which has no contact hole in each memory cell. Moreover, since the inversion layer formed in the p-well 201 is used for the local data line, it is not necessary to form a separate diffusion layer for the local data line in the memory array. Therefore, the pitch of the data line can be made smaller, so that it is possible to achieve an increase in the integration of a memory cell.

Moreover, a flash memory of the present invention has the following features.
(1) The gate width (WG3) of the assist gate 223a is 10% or greater than the gate length (LG1) of the floating gate 221b.
(2) The film thickness (Tox3) of the gate oxide film 213 formed underneath the assist gate 223a is smaller than the film thickness (Tox1) of the gate oxide film 211 formed underneath the floating gate 221b, for instance, Tox3=7 nm or less and Tox1=9 nm or more.
(3) The dopant concentration of the p-well 201 underneath the assist gate 223a is lower than the dopant concentration of the p-well 201 underneath the floating gate 221b (the channel dopant high-concentration region is shown as the code 205).

The following effects are achieved by having the aforementioned structure.

(a) Since the electrical resistivity of the inversion layer formed underneath the assist gate 223a is decreased, the reading characteristics and programming characteristics are improved.

(b) Since the boost voltage (Vboost) of the inversion layer is increased while programming, the programming speed is improved.

(c) Since the opposing areas of both adjacent floating gates 221b become smaller, the threshold voltage shift caused by the capacitive coupling between the floating gates 221b is suppressed.

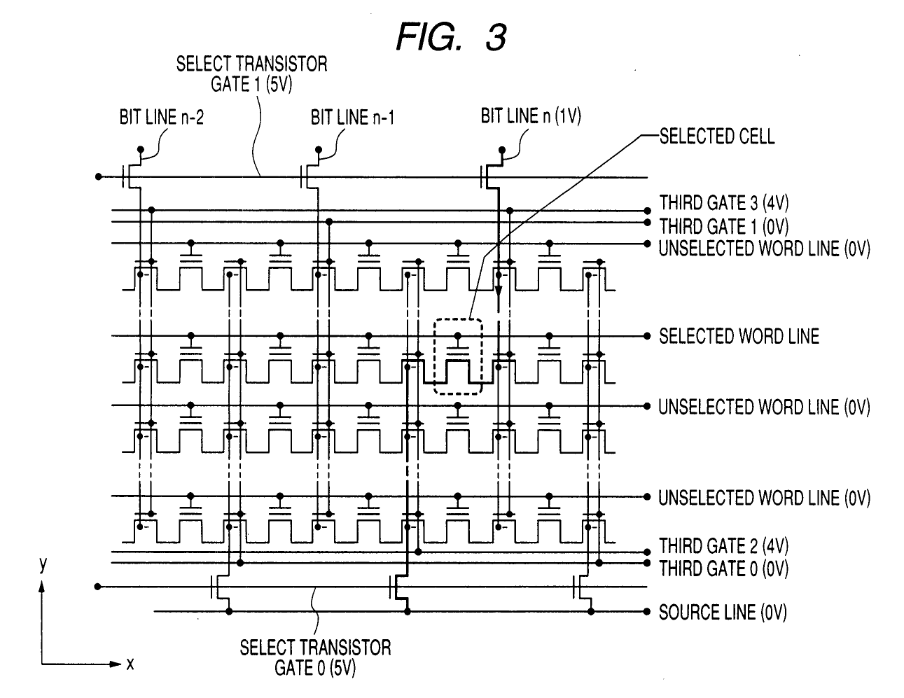

FIG. 3 is a circuit diagram of a memory array illustrating a voltage condition of a flash memory of this embodiment while reading.

In this embodiment, the assist gates 223a form a unit, for instance, every four lines. In the case of four assist gates (0-3) shown in the figure, a voltage is supplied from the bit line to the inversion layer formed underneath each of the assist gate (1) and the assist gate (3). Moreover, a voltage is supplied from the common source line to the inversion layer formed underneath each of the assist gate (0) and the assist gate (2).

While reading, a voltage of about 5 V is biased to the gates (0, 1) of the selected transistor (Q) arranged at both ends of the memory array and about a voltage of 4 V is biased to the assist gates (2, 3) at both ends of the selected memory cell (selected cell), thereby, an inversion layers are formed on the surface of the substrate underneath the assist gates (2, 3) and they are used as a source and a drain. The unselected cell is made OFF state by biasing 0 V or a negative voltage of −2 V, in some cases, to the unselected word line, and the threshold voltage of the selected cell is determined by biasing a voltage to the word line WL (selected word line) connected to the selected cell. It is possible to read data in parallel from every four memory cells connected to one word line.

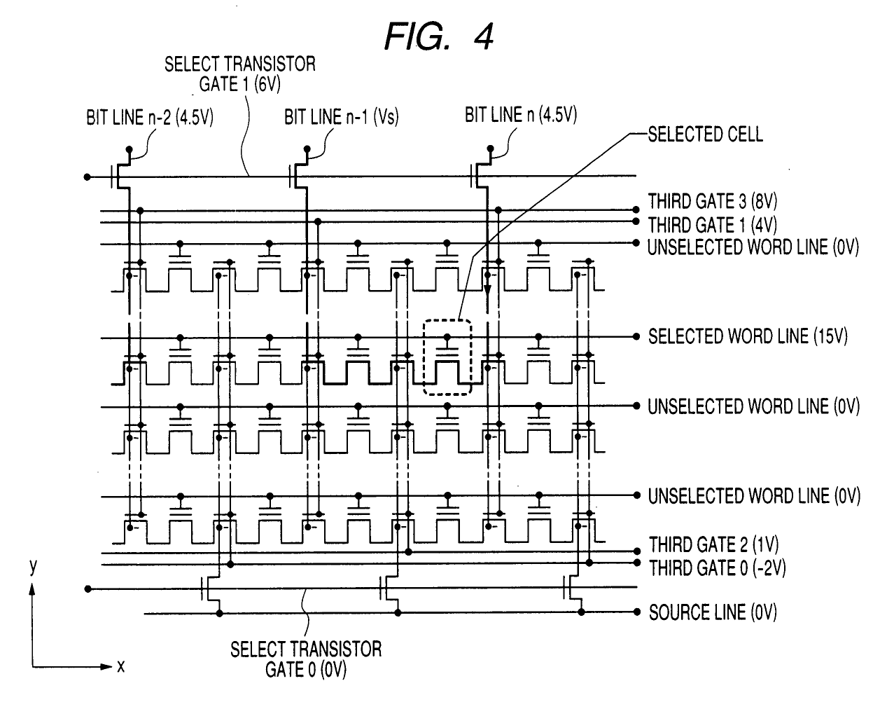

FIG. 4 is a circuit diagram of a memory array illustrating a voltage condition of a flash memory of this embodiment while programming.

Programming is carried out by using a source side hot electron injection technique under the following conditions. At first, voltages of about 6 V, about 4.5 V, and about 15 V are biased to the gate (1) of the select transistor (Q) of the bit line side, the bit line (n), and the selected word line, respectively. Moreover, the p-well 201 is maintained at 0 V by biasing the assist gate (3) of the bit line (n) side and the assist gate (1) of the bit line (n−1) side to be voltages of about 8 V and about 4 V, respectively. Furthermore, a voltage of about 1 V is biased to the assist gate (2).

In the case when the voltage (Vs) supplied to the bit line (n−1) is controlled to be 0 V, the surface of the substrate underneath the assist gate (2) becomes a weak inversion state, and a channel current is created between the bit line (n) and the bit line (n−1) through the channel of the selected cell. At this time, hot electrons are generated in the channel between the selected cell and the assist gate (2), resulting in electrons being injected in the selected cell. On the other hand, when the voltage (Vs) supplied to the bit line (n−1) is controlled to be about 2 V, a channel current does not flow under the assist gate (2), so that programming does not occur.

Programming data can be made in parallel to every four memory cells connected to one word line, and programming/unprogramming is controlled by the voltage (Vs) supplying to the bit line. 0 V or a negative voltage about −2 V is biased to the unselected word line while programming and the channel underneath the unselected cell is made OFF state. Moreover, isolation characteristics are ensured by biasing 0 V or a negative voltage about −2 V to the assist gate (0).

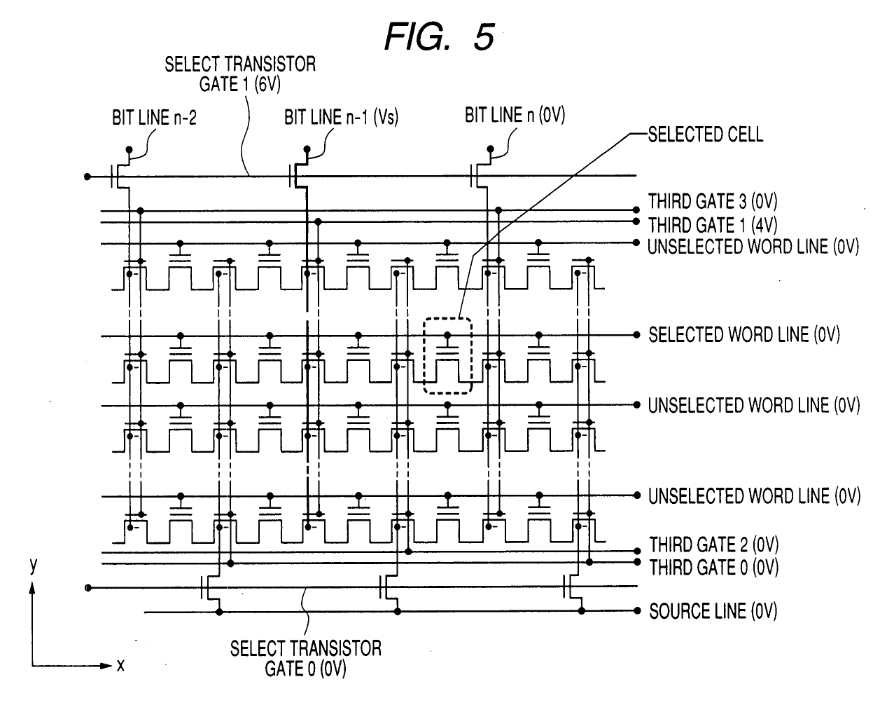

In the programming described above, the surface of the substrate (p-well 201) underneath the assist gate (2) becomes a weak inversion state, so that the channel current flowing through the memory cell greatly depends on the threshold voltage of the assist gate (2). Therefore, when the channel current varies, the programming speed varies. Hereinafter, using FIGS. 5 to 8, a technology to reduce the variability of the programming speed caused by the variability of the channel current will be explained (refer to 2004 Symposium on VLSI Circuits pp. 72-73).

At first, as shown in FIG. 5, voltages of about 6 V, about 4 V, and (Vs) are biased to the gate of the select transistor (Q), the assist gate (1), and the bit line (n−1), respectively. The voltage (Vs) is controlled to be 0 V in the case when the memory cell is in the process of programming and to be about 2 V in the case of not programming. By doing it in this manner, a voltage (Vs) which is the same as the one of the bit line (n−1) is supplied to the inversion layer formed underneath the assist gate (1).

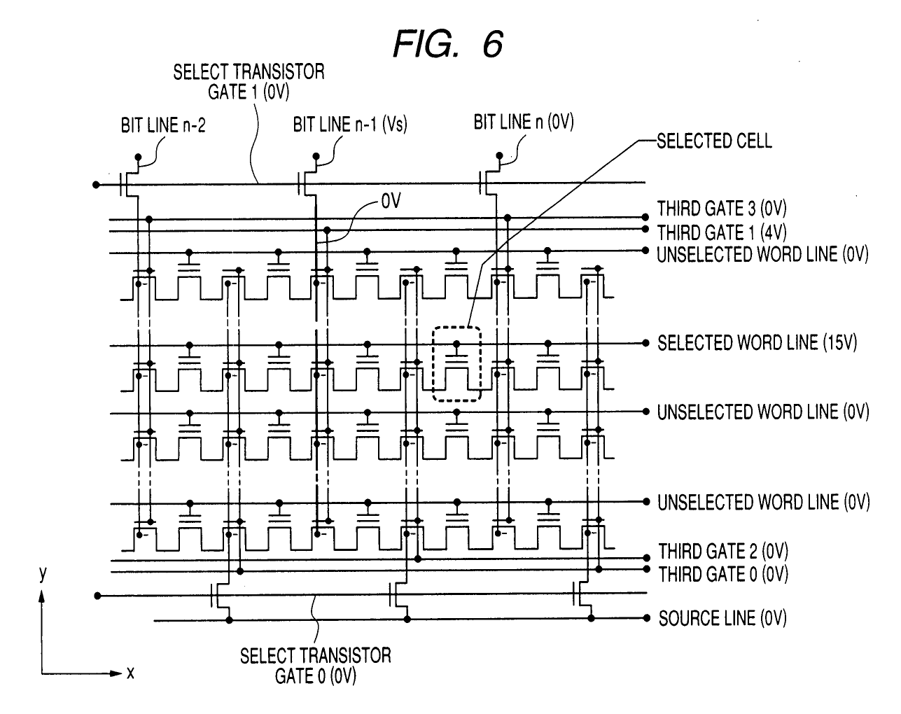

Next, as shown in FIG. 6, this select transistor (Q) is made OFF state by controlling the gate (1) of the select transistor (Q) of the bit line side to be 0 V. By doing it like this, the inversion layer underneath the assist gate (1) is shielded from the bit line (n−1) and becomes a floating state, however, the voltage (Vs) remains in the original state.

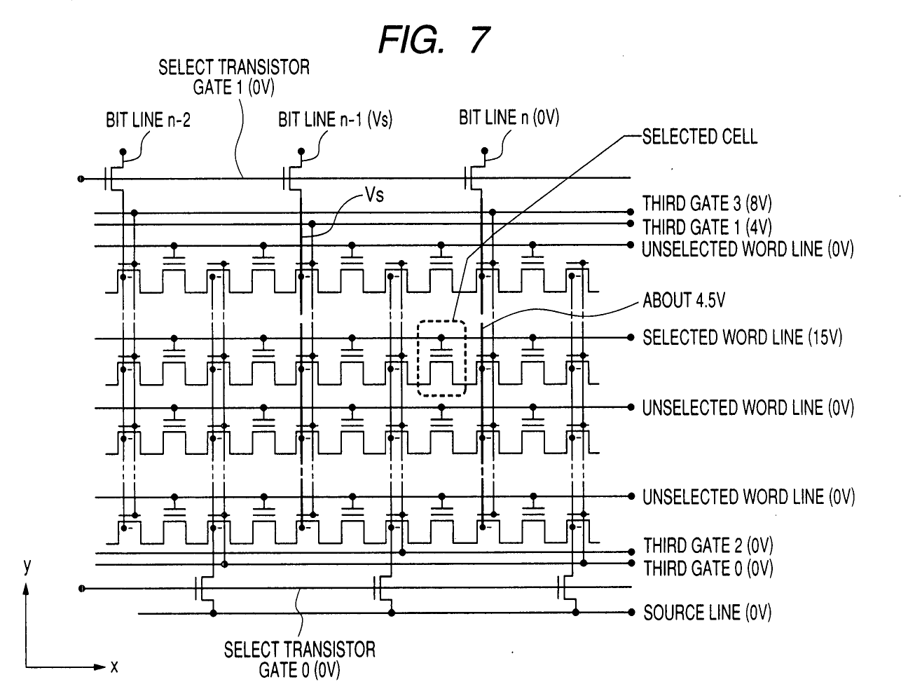

Next, as shown in FIG. 7, voltages of 8 V and 15 V are biased to the assist gate (3) and the selected word line, respectively. At this time, since the gate (1) of the select transistor (Q) is OFF state, the surface of the substrate underneath the assist gate (3) is a floating state. However, when the voltage of the assist gate (3) is increased within a time less than 1 μs, the voltage of the surface of the substrate is also increased.

Herein, the boost voltage (Vboost) at the surface of the substrate can be expressed as follows using the gate oxide capacitance Cox of the assist gate (3), the depletion layer capacitance of the substrate underneath the assist gate (3), and the voltage (V3) of the assist gate (3).
Vboost=Cox/(Cox+Cdep)×V3 (1)
In order for programming to be induced as a result of the injection of source-side hot electrons, the boost voltage (Vboost) at the surface of the substrate has to be 3.5 V or more.

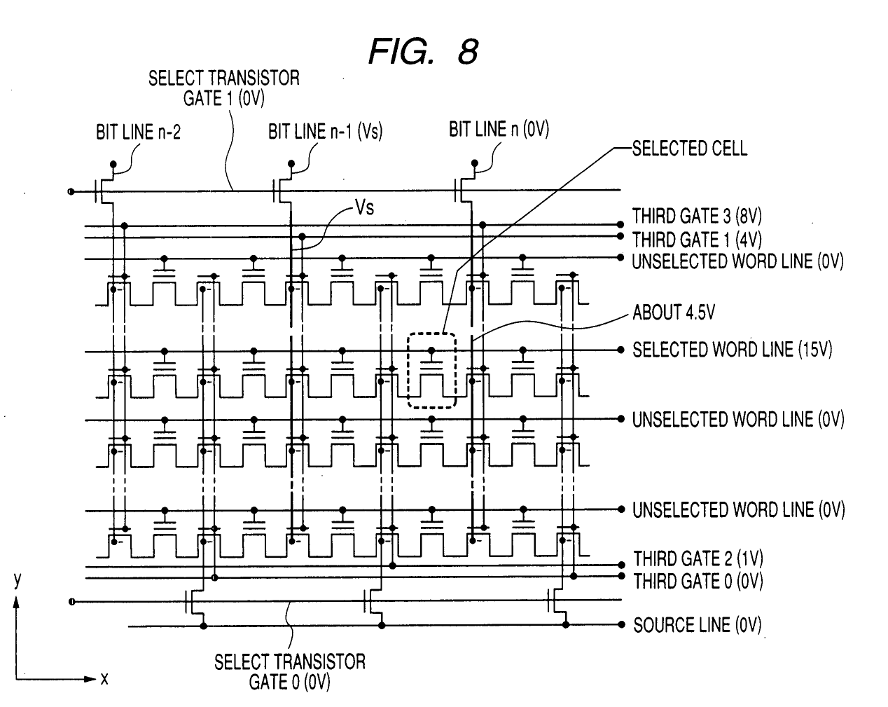

As shown in FIG. 8, when about 1 V is biased to the assist gate (2), in the case when the voltage (Vs) of the inversion layer underneath the assist gate (1) is 0V, a channel current flows through the channel underneath the memory cell, in the gap of the inversion layer (voltage=Vboost) underneath the assist gate (3), resulting in programming of the selected cell being preformed by source side-hot electron injection. At this time, since the select transistor (Q) is in OFF state, both inversion layers are shielded from the bit line, so that they become floating state. Charge transfer is generated between the two inversion layers by a channel current, and it is cut off by the assist gate 223a (2) by increasing the voltage of the inversion layer underneath the assist gate (1), resulting in the current being stopped. On the other hand, in the case of the voltage (Vs) being about 2 V, the assist gate (2) is cut off and the channel current does not flow through the memory cell, resulting in programming being not performed.

Even in the case when a channel current flows with a voltage (Vs)=0 V, since the voltage difference between the inversion layers underneath the assist gate (3) and the assist gate (1), the hot electron injection current decreases. Therefore, this programming occurs mainly at the initial stage when the voltage difference between both inversion layers is large, and, even if the amount of charge transfer is made greater than a certain value, the programming does not proceed. Even if the threshold voltage of the assist gate (2) varies, making the value greater in order to generate sufficient charge transfer in all memory cells suppresses the variability in programming. While programming, 0V or a negative voltage of about −2 V is biased to the unselected word line, and the channel underneath the unselected cell is made OFF state. Moreover, isolation characteristics are ensured by biasing 0 V or a negative voltage of about −2 V to the assist gate (0).

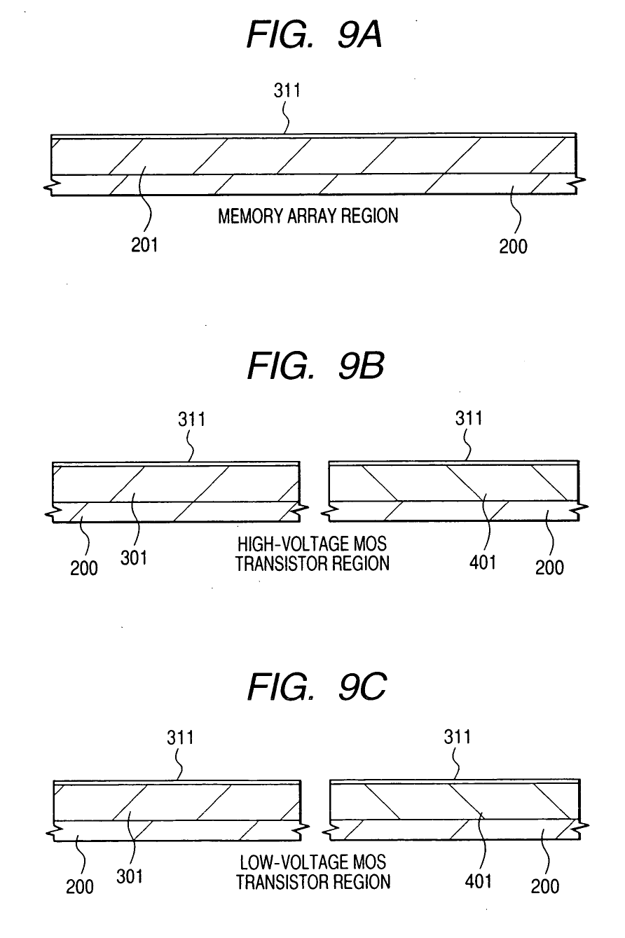

Next, FIGS. 9A to 18C illustrate one example of a manufacturing method of the aforementioned flash memory. At first, as shown in FIGS. 9A, 9B, and 9C, a p-well 201 is formed in the memory array region of the substrate 200. After a p-well 301 and an n-well 401 are formed in the peripheral circuit region (high-voltage MOS transistor region and low-voltage MOS transistor region) of the substrate 200, a gate oxide film 311 with a film thickness of 20 to 30 nm is formed by, for instance, a thermal oxidation method at each surface of the p-wells 201 and 301, and n-well 401. The gate oxide film 311 formed on the peripheral circuit region consists of the gate insulator film of the high voltage MOS transistor. The dopant concentration of the p-well 201 of the memory array region can be decreased to be a level at which isolation becomes possible by biasing a negative voltage of about −2 V to the assist gate.

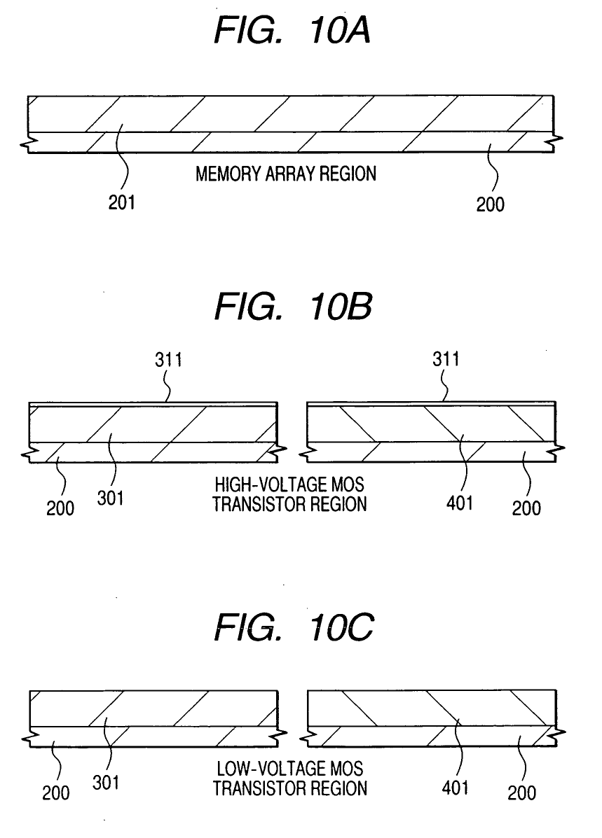

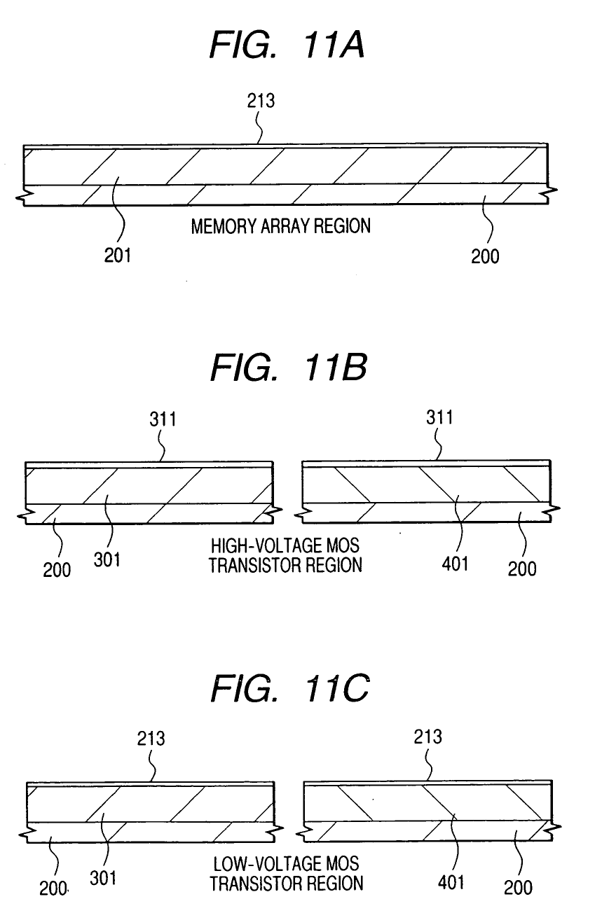

Next, after removing a part of the peripheral circuit region (low-voltage MOS transistor region) and the gate oxide film 311 in the memory array region by a wet etching technique as shown in FIGS. 10A, 10B, and 10C, a gate oxide film 213 with a film thickness of about 7 nm is formed in these regions by, for instance, a thermal oxidation method as shown in FIGS. 11A, 11B, and 11C.

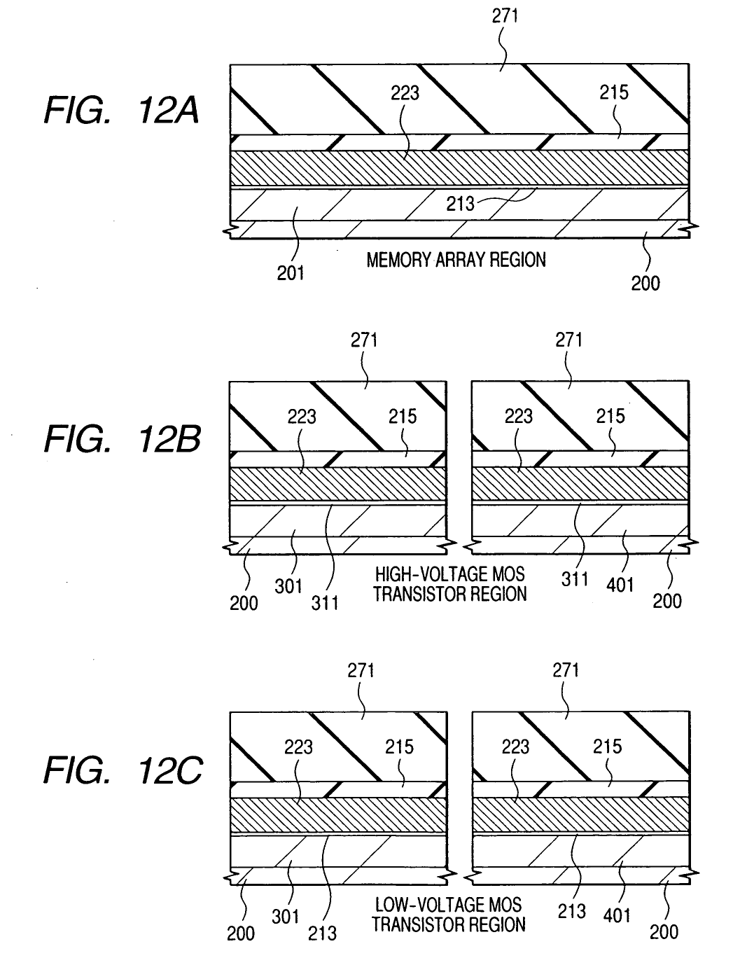

Next, as shown in FIGS. 12A, 12B, and 12C, a phosphor-doped polysilicon film 223, a silicon nitride 215, and a dummy silicon oxide film 271 are deposited, in order, on the substrate 200 by using, for instance, a CVD (Chemical Vapor Deposition) technique. The polysilicon film 223 comprises the assist gate 223a and the gate of the MOS transistor of the peripheral circuits.

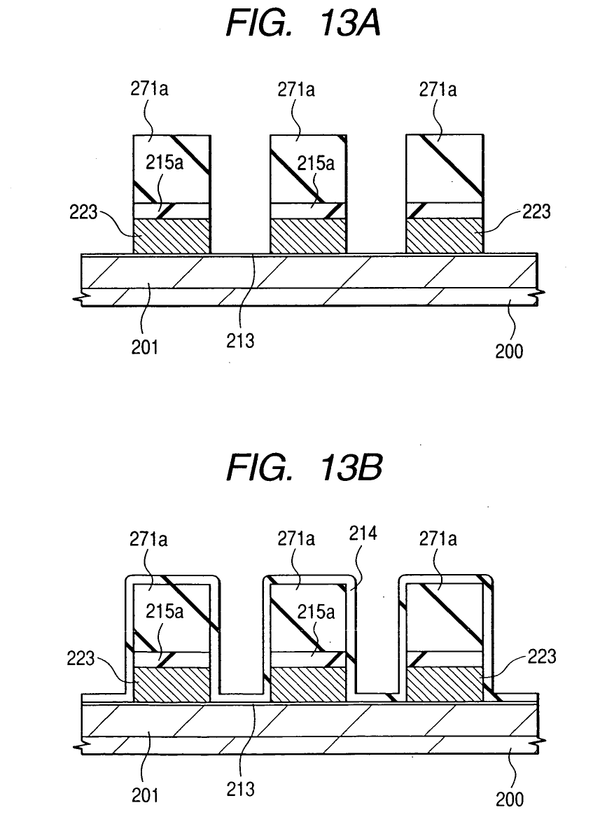

In the following explanation, only the memory array region is shown in the figures. Next, as shown in FIG. 13A, the aforementioned dummy silicon oxide film 271, the silicon nitride film 215, and the polysilicon film 223 are patterned by lithography and dry etching techniques. According to this patterning, the dummy silicon oxide film 271 and the silicon nitride film 215 become the dummy silicon oxide film 271a and the silicon nitride film 215a, respectively. These films, the dummy silicon oxide film 271a, the silicon nitride film 215a, and the polysilicon film 223, are patterned in a stripe shape to be formed lying in a linear direction. The polysilicon film 223 is patterned to make the gate width (WG3) of the assist gate 10% or greater than the gate length (LG1) of the floating gate to be formed later. Moreover, it is necessary that the silicon oxide film 214 to be formed later to insulate the assist gate and the floating gate has a film thickness of about 25 nm, so that when the pitch is assumed to be 2 F,
LG1=2×F−25 nm×2−WG3 (2)
Herein, in order to make
WG3>LG1×1.1=1.1×(2×F−25 nm×2−WG3) (3)
it should be
WG3>(2.2×F−55 nm)/2.1 (4)
The gate width (WG3) of the assist gate may become, for instance, about 30 nm smaller in the process for forming an insulator film to be performed later. It is necessary that the dimension of this step be assumed to be as follows.
WG3−30 nm>(2.2×F−55 nm)/2.1 (5)
For instance, the value of right side is 98.1 nm using the F 90 nm rule and 71.9 nm using the 65 nm rule.

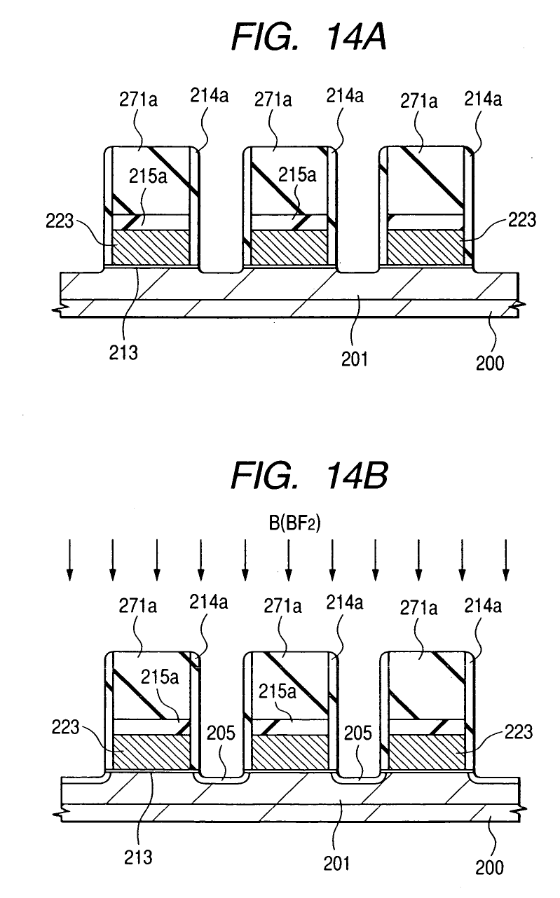

Next, as shown in FIG. 13B, the silicon oxide film 214 having a film thickness, in which the space section of the aforementioned stripe-shaped pattern is not completely buried, is deposited by using a CVD technique, and then the side-wall shaped silicon oxide film 214a is formed on the sidewalls of the dummy silicon oxide film 271a, the silicon nitride film 215a, and the polysilicon film 223 by selectively etching back the silicon oxide film 214 as shown in FIG. 14A. At this time, in the space section of the stripe-shaped pattern formed lying in the aforementioned line direction, the gate oxide film 213 is also removed. Moreover, even though there is a selection ratio, the surface of the p-well 201 is also etched from about several nanometers to ten nanometers.

Next, as shown in FIG. 14B, the channel dopant high-concentration region 205 is formed by performing boron (B) ion (or BF₂ ion) implantation to the surface of the p-well 201 using the dummy silicon oxide film 271a as a mask. The floating gate is formed later at the top of the channel dopant high-concentration region 205. Since the dopant concentration of the p-well 201 is low, the neutral threshold voltage of the memory cell is decreased to an extreme by a short-channel effect of the floating gate transistor in the case when a memory cell is formed without performing the aforementioned ion implantation. Therefore, the neutral threshold voltage can be controlled to be about 1 V to 2 V by performing an additional dopant ion implantation as mentioned above. By not performing ion implantation to all areas of the channel region but only to the region on which the floating gate is formed, the threshold voltage of the memory cell can be controlled and the channel dopant concentration underneath the assist gate can be kept to a low concentration. Therefore, as mentioned later, since the electric resistance of the inversion layer formed underneath the assist gate can be decreased, it is possible to improve the programming speed and the reading characteristics. Moreover, since the boost voltage (Vboost) can be increased, the programming speed using a Constant-charge-Injection Programming method (CCIP) becomes greater.

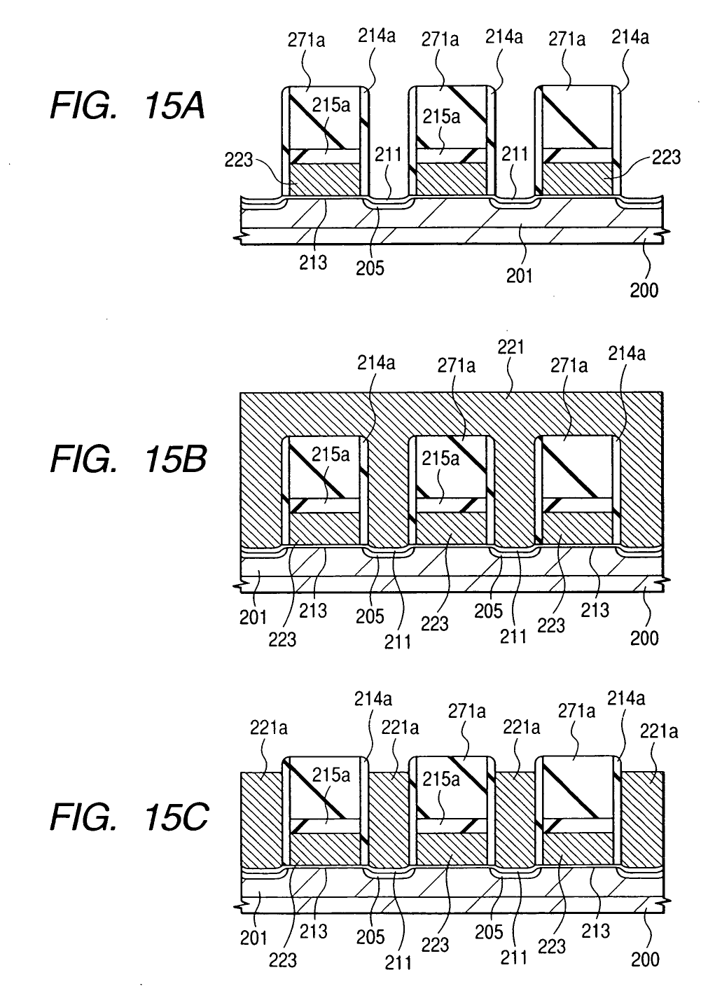

Next, as shown in FIG. 15A, the gate oxide film 211 is formed on the surface of the p-well 201 to which the aforementioned dopants are injected (channel dopant high-concentration region 205) by using a thermal oxidation technique (or a CVD technique). It is necessary that the film thickness of the gate oxide film 211 be controlled to be about 9 nm or more in order to insulate between the floating gate and the p-well 201 and to maintain the information programmed in the memory cell, so that it is made thicker than the gate oxide film 213 (about 7 nm) underneath the assist gate. Next, as shown in FIG. 15B, the polysilicon film 221 is deposited with a thick film thickness so as to completely bury the space at the top of the gate oxide film 211. Then, as shown in FIG. 15C, using an etchback technique or a chemical mechanical polishing (CMP) technique, the polysilicon film 221 is etched back until the surface of the dummy silicon oxide film 271a becomes exposed, resulting in the floating gate 221a being formed.

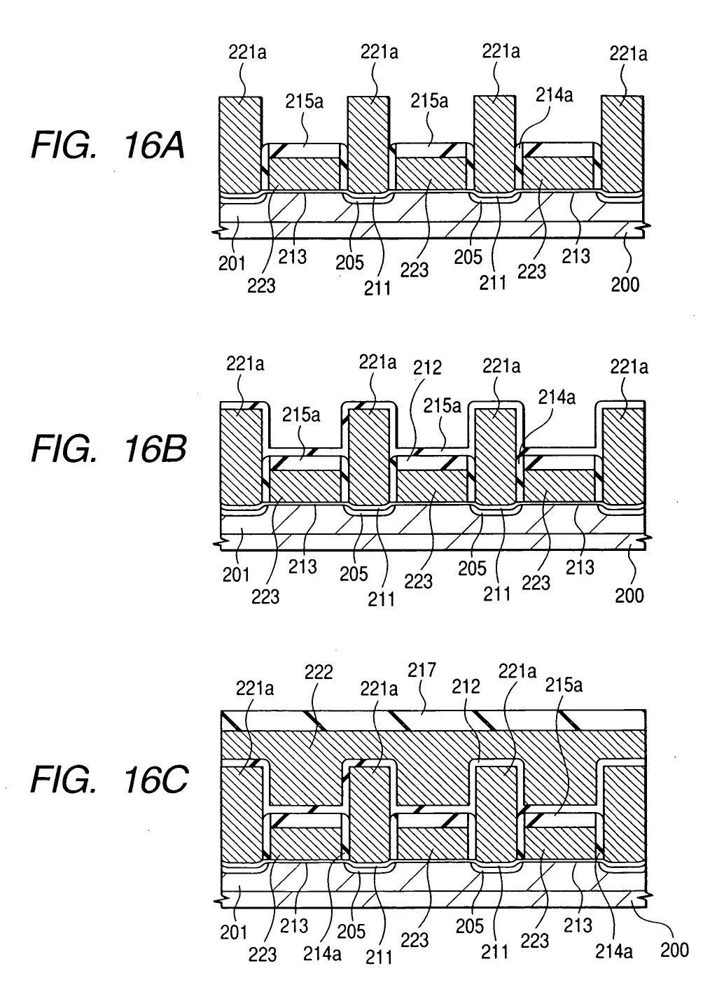

Next, as shown in FIG. 16A, the surface of the silicon nitride 215a is exposed by dry-etching or wet-etching the dummy silicon oxide film 271a and the oxide silicon film 214a on the side wall thereof. Next, as shown in FIG. 16B, the insulator film 212 which electrically insulates the floating gate 221a and the control gate is formed on top of the silicon nitride film 215a and the floating gate 221a. This insulator film 212 consists of, for example, a silicon oxide film deposited by a CVD technique or a stacked film of silicon oxide film/silicon nitride film/silicon oxide film. Next, as shown in FIG. 16C, a stacked layer of a polysilicon film and a tungsten silicide film or a poly-metal film (a stacked layer of a polysilicon film, a tungsten nitride film, and a tungsten film) is deposited by a CVD technique as a control gate material on top of the insulator film 212, and the silicon oxide film 217 is deposited by a CVD technique on top of the control gate material 222.

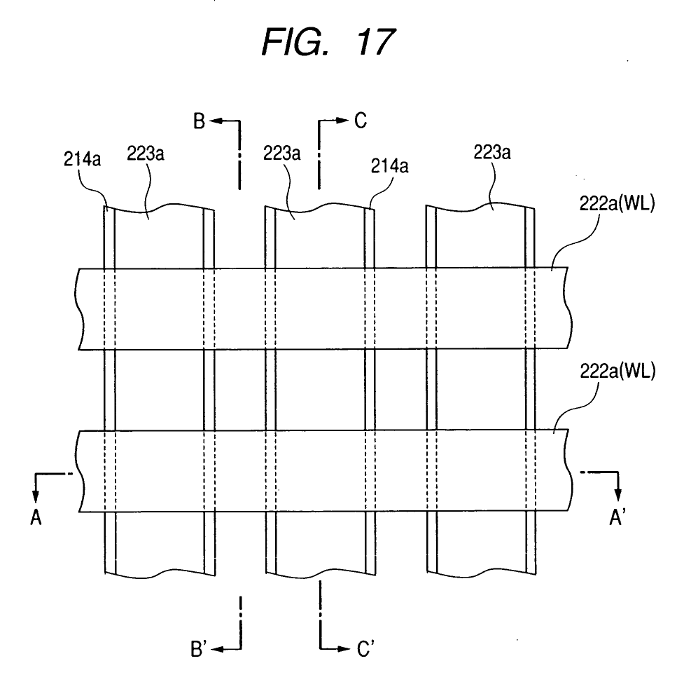

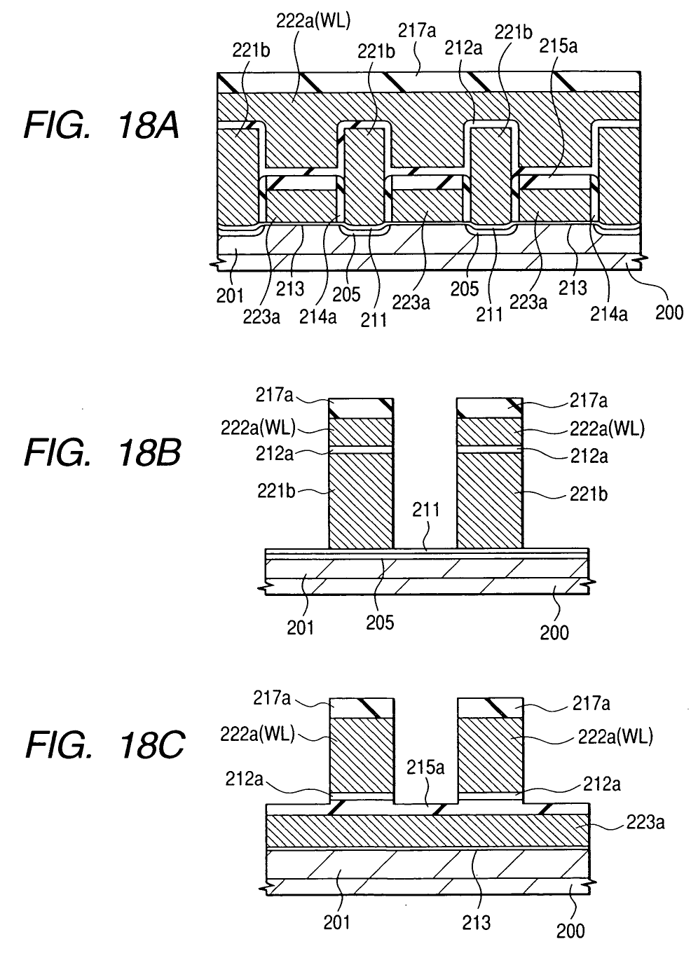

Next, as shown in FIG. 17, FIG. 18A (line cross-section A-A′ of FIG. 17), FIG. 18B (line cross-section B-B′ of FIG. 17), and FIG. 18C (line cross-section C-C′ of FIG. 17), the control gate 222a (word line WL) is formed by patterning the silicon oxide film 217 and the control gate material 222 by using lithography and dry etching techniques. The control gate 222a, the insulator film 212, and the floating gate 221a are processed in one step by using a stripe-shaped mask pattern lying in the line direction while patterning. The floating gate 221a lying in the line direction becomes the floating gate 221b separated in each memory cell by this patterning. Moreover, the second insulator film 212 remains underneath the control gate 222a and becomes the second insulator film 212a which electrically separates the control gate 222a and the floating gate 221a.

Next, on top of the control gate 222a (word line WL), a silicon oxide film 216a is formed, which functions as an interlayer dielectric film (refer to FIG. 2). Afterwards, although it is omitted in the figure, a contact hole reaching the word line WL, the p-well 201, and the assist gate 223a, and a contact hole for feeding power to the inversion layer are formed by etching the silicon oxide film 216a. Then, a metallic film deposited on the silicon oxide film 216a is patterned to form a circuit, resulting in a memory cell being completed.

The memory cell of this embodiment completed in this fashion has a gate width (WG3) of the assist gate 223a>1.1×the gate length (LG1) of the floating gate 221b; a film thickness of the gate oxide film 213 underneath the assist gate 223a of (about 7 nm or less)<the film thickness of the gate oxide layer 211 underneath the floating gate 221b (about 9 nm); and a channel dopant concentration underneath the assist gate 223a<the channel dopant concentration underneath the assist gate 221b.

Moreover, since the memory cell of this embodiment can increase the boost voltage (Vboost), the programming can be performed at high speed using a Constant-Charge-Injection Programming method (CCIP) which has small programming variability.

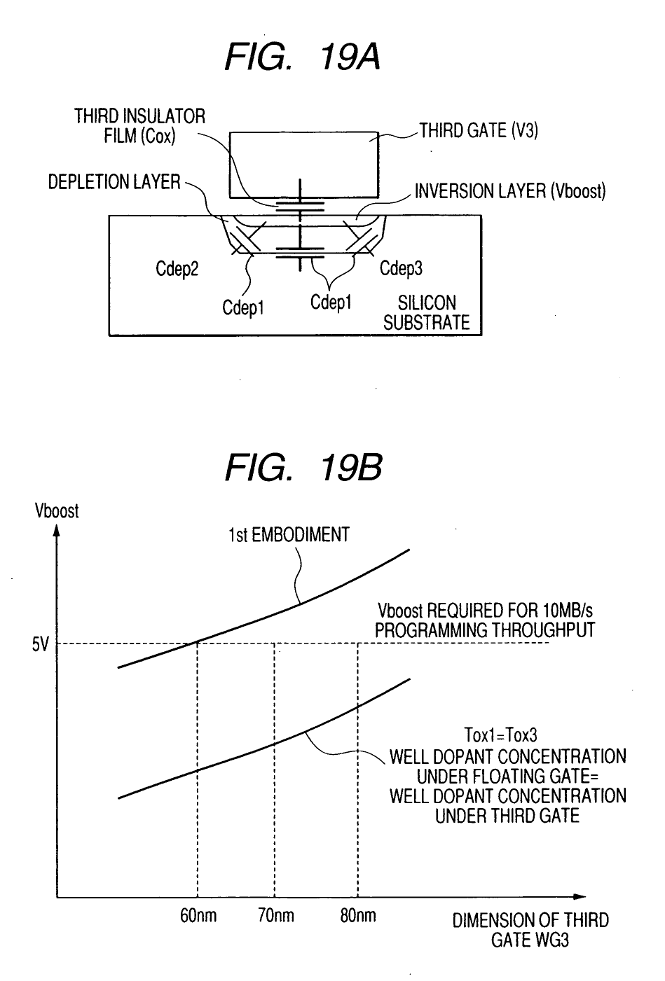

FIG. 19A shows the corresponding parts of the gate oxide film capacitance (Cox) and the depletion layer capacitance (Cdep) of the assist gate. Cox increases in proportion with the assist gate width (WG3). When the proportion coefficient is assumed to be kox>0,
Cox=kox×WG3 (6)

On the other hand, the depletion layer capacitance (Cdep) consists of Cdep1, Cdep2, and Cdep3, in which Cdep1 becomes greater proportionately with the gate width (WG3) of the assist gate 223a (the proportion coefficient is assumed to be kdep1>0), but the fringe component of the depletion layer capacitance Cfringe>0 almost never depends on the gate width (WG3).
Cfringe=Cdep2+Cdep3 (7)
Cdep=Cdep1+Cdep2+Cdep3=kdep1×WG3+Cfringe (8)

Therefore, when the gate width (WG3) increases,
Cox/(Cox+Cdep)=(kox×WG3)/(kdep1×WG3+Cfringe) (9)
increases. Moreover, when the film thickness of the gate oxide film 213 underneath the assist gate 223a is made thinner, Cdep does not change and Cox increases, so that Cox/(Cox+Cdep) increases. When the channel dopants underneath the assist gate 223a are controlled to be a low concentration, Cdep is decreased and Cox/(Cox+Cdep) increases. When Cox/(Cox+Cdep) increases, according to the expression (1), the boost voltage (Vboost) increases in the case of using a constant assist gate voltage (V3) (refer to FIG. 19B).

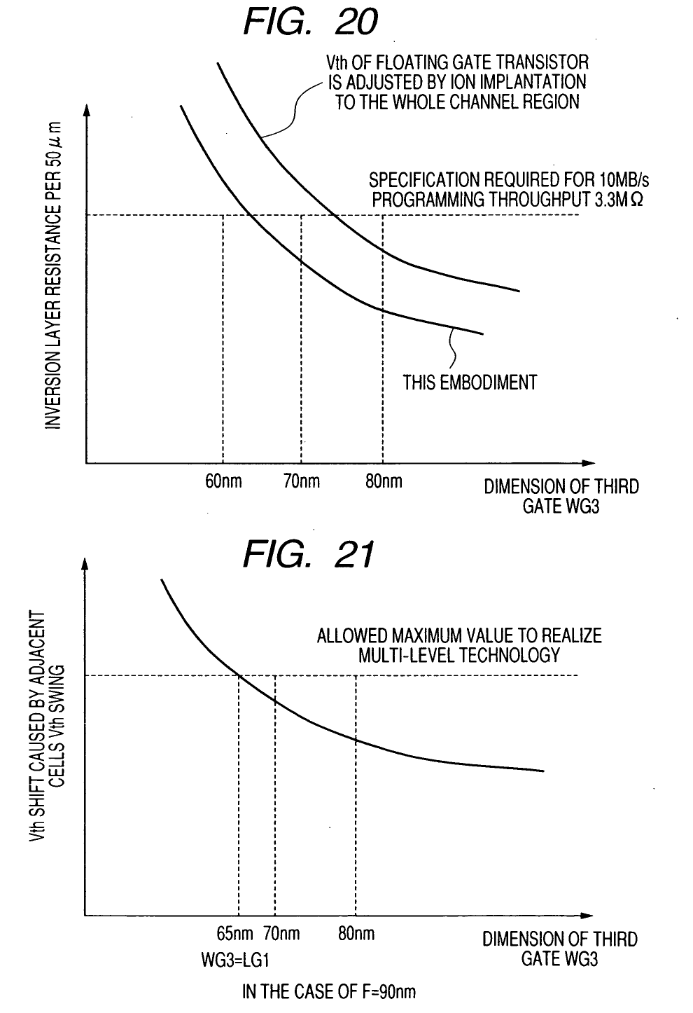

Moreover, as shown in FIG. 20, the resistance of the inversion layer is decreased by an increase in the gate width (WG3) and a decrease in the channel dopant concentration underneath the assist gate 223a. Moreover, since the gate length (LG1) of the floating gate is small, as shown in FIG. 21, the opposing areas of the floating gate 222a in the region between the adjacent word lines WL decreases. As a result, the threshold voltage shift caused by the capacitance coupling between the floating gates can be reduced.

The matters which are of concern in a memory cell of this embodiment are that of the isolation characteristics attributable to the assist gate 223a being deteriorated by a decrease in the channel dopant concentration underneath the assist gate 223a and that of the threshold voltage of the floating gate transistor being decreased by a decrease in the gate length (LG1) of the floating gate. However, the isolation characteristics of the assist gate 223a can be improved by biasing a negative voltage of about −2 V to the assist gate 223a and a means can be taken for decreasing the threshold voltage of the floating gate transistor by ion implantation of the channel dopant which is carried out in the aforementioned process of FIG. 14B.

### Second Embodiment

In the aforementioned first embodiment, a thick gate oxide film (film thickness=20 to 30 nm) for a high-voltage transistor and a thin gate oxide film (film thickness=about 7 nm) for a low-voltage transistor are used as gate oxide films for the peripheral circuits. Herein, the thin gate oxide film with a thickness of about 7 nm is formed simultaneously with the gate oxide film 213 of the assist gate 223a in the memory array region. That is, the gate oxide film 213 is formed simultaneously in the process for forming the thin gate oxide film of the peripheral circuits. However, in this situation, there is a case where the characteristics of the gate oxide film 213 are limited by the characteristics of the low-voltage MOS transistor of the peripheral circuits. Then, in this embodiment, the aforementioned problem is solved by forming the thin gate oxide film of the peripheral circuits and the gate oxide film underneath the assist gate in different processes.

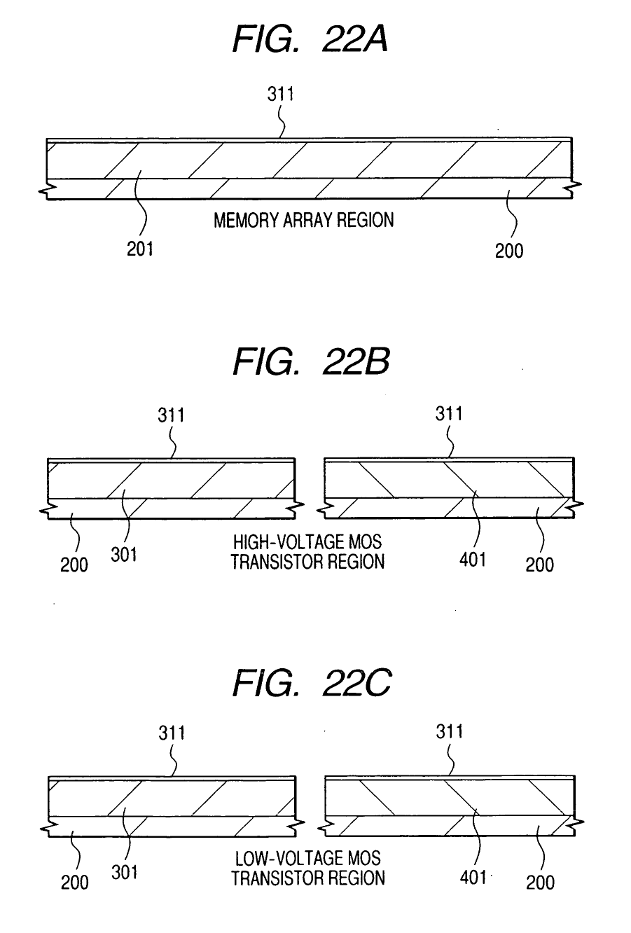

At first, as shown in FIG. 22A, a p-well 201 is formed on a substrate 200 in the memory array region and, as shown in FIGS. 22B and 22C, a p-well 301 and an n-well 401 are formed on the substrate 200 in the peripheral circuits. Then, a gate oxide layer 311 having a film thickness from 20 to 30 nm is formed by using a thermal oxidation technique on each surface of the p-wells 201 and 301 and the n-well 401. The dopant concentration of the p-well 201 in the memory array region can be reduced to a level in which isolation is possible by biasing a negative voltage of about −2 V to the assist gate.

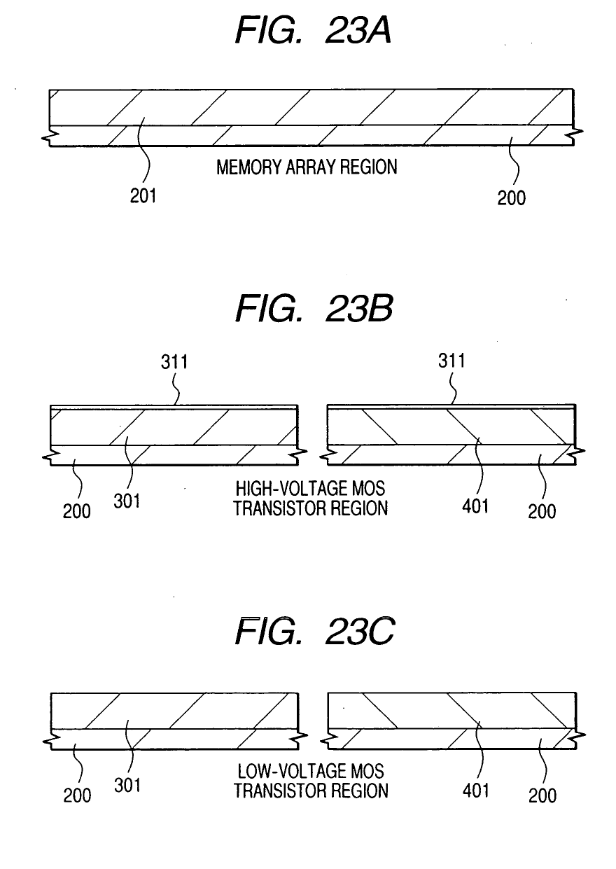

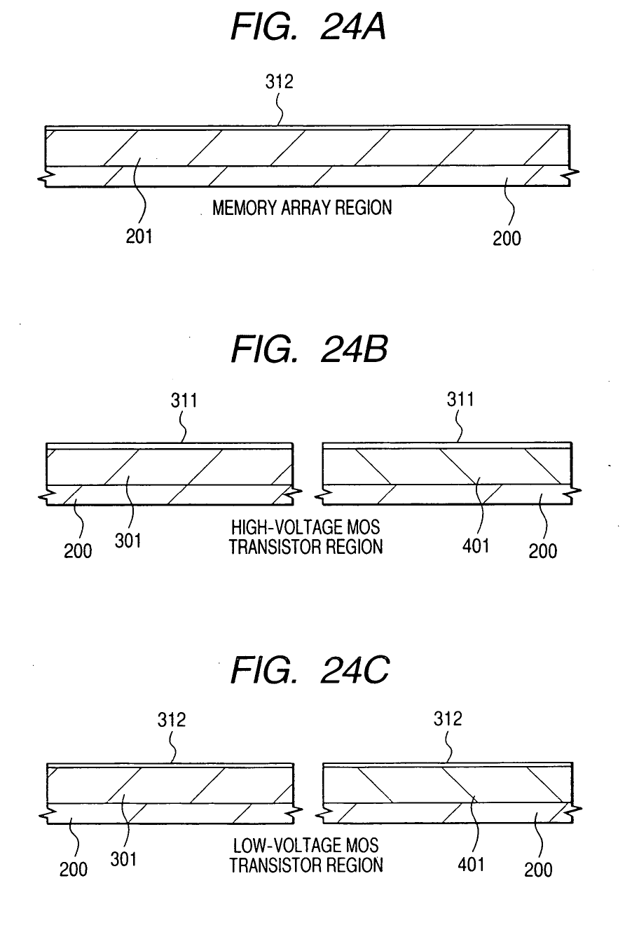

Next, after the gate oxide film 311 in a part of the peripheral circuits (low-voltage MOS transistor region) and in the memory array region is removed by using dry-etching and wet-etching techniques as shown in FIGS. 23A, 23B, and 23C, a gate oxide film 312 having a film thickness of about 7 nm is formed in these regions by using a thermal oxidation technique as shown in FIGS. 24A, 24B, and 24C.

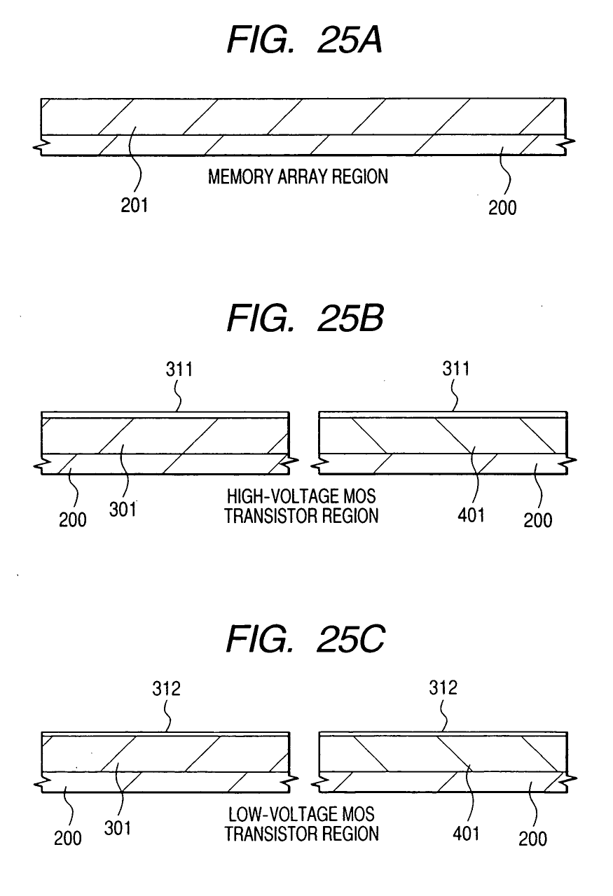

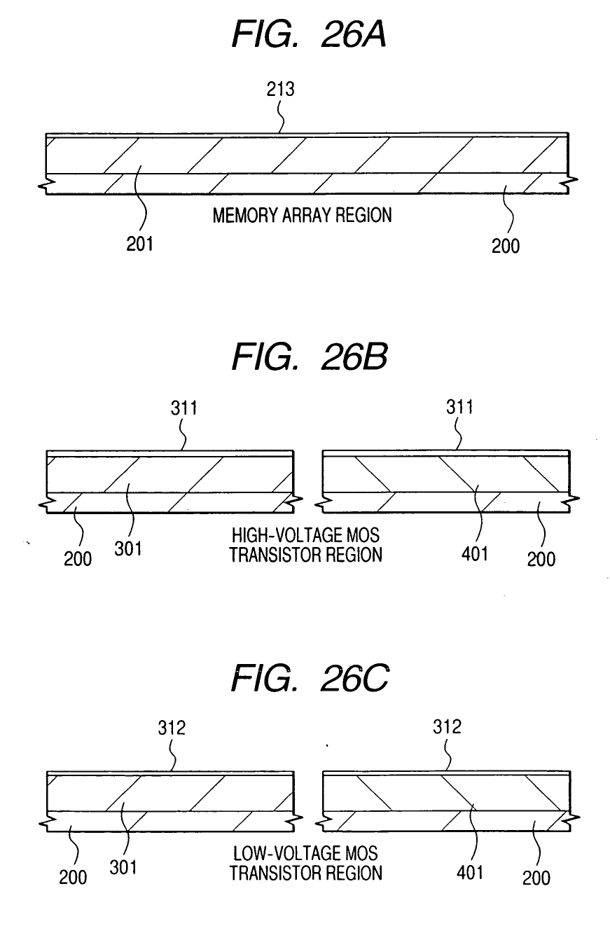

Next, after only the gate oxide film 312 in the memory array region is selectively removed by using dry-etching and wet-etching techniques as shown in FIGS. 25A, 25B, and 25C, a thin gate oxide film 213 having a film thickness of about 6 nm or less is formed on the surface of the p-well 201 in the memory array region by using a thermal oxidation technique as shown in FIGS. 26A, 26B, and 26C. The film thickness of the gate oxide layer 311 in the peripheral circuits becomes several nanometers thicker when the gate oxide films 312 and 213 are formed, so that the gate oxide film 312 in the peripheral circuits becomes even thicker by several nanometers when the gate oxide film 213 is formed. Therefore, in the step for forming the gate insulator film 213, the film thickness of the thick gate oxide film 311 in the peripheral circuits becomes from 20 nm to 30 nm or more, resulting in the film thickness of the thin gate film 312 becoming 7 nm or more.

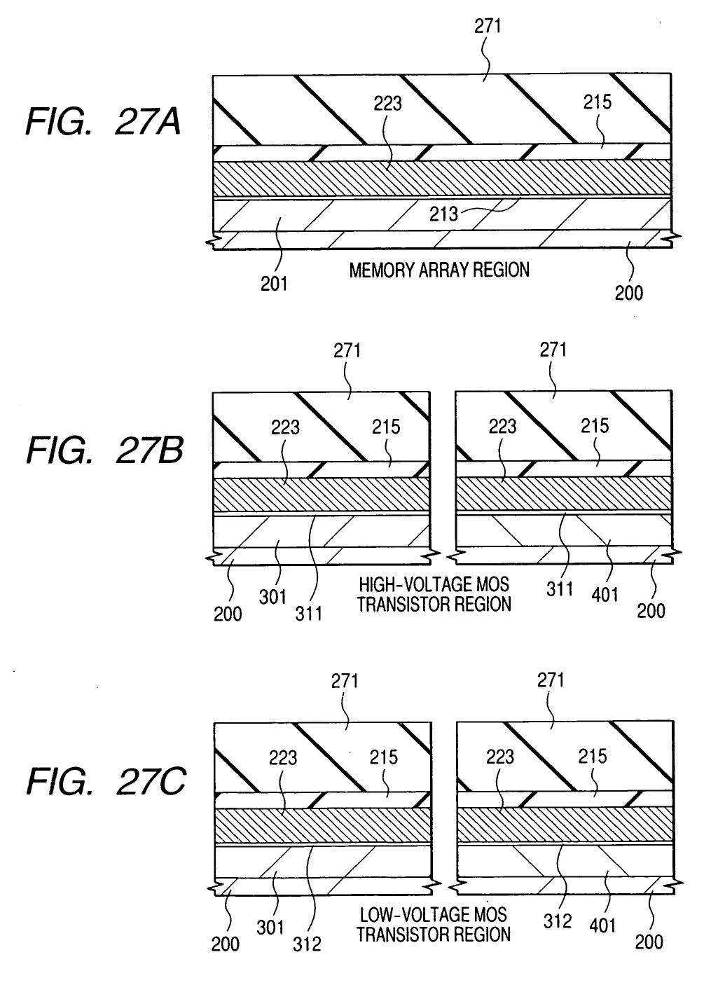

Next, as shown in FIGS. 27A, 27B, and 27C, a phosphorus (P)-doped polysilicon film 223, a silicon nitride film 215, and a dummy silicon oxide film 271 are deposited on the substrate 200, in order, by using a CVD technique. After that, a memory cell is formed by following the process shown in FIG. 13 to FIG. 18 of the aforementioned embodiment.

According to the manufacturing method of this embodiment, the film thickness of the gate oxide film 213 of the assist gate 223 can be made thinner without limiting the characteristics of the transistor of the peripheral circuits. Therefore, the boost voltage (Vboost) can be further increased compared with the memory cell of the aforementioned first embodiment, resulting in the programming speed being able to be increased even further.

### Third Embodiment

In the first and second embodiments, the level of the surface of the substrate in the region between the floating gates adjoined in the row direction was the same.

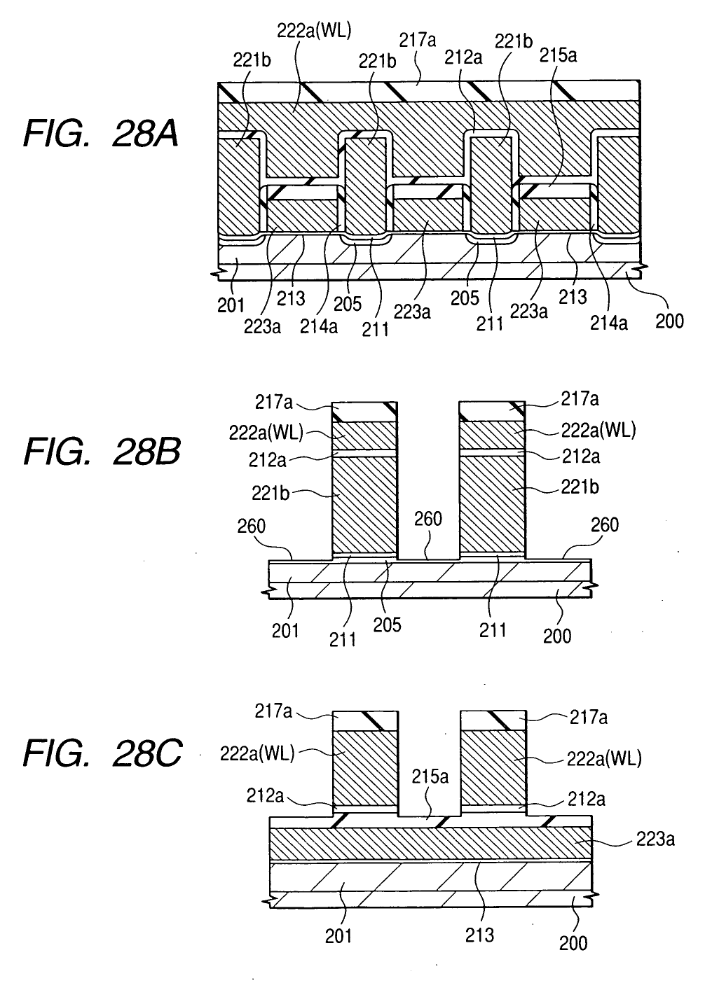

In this embodiment, after the processes for forming in one step the control gate 222a, the second insulator film 212a, and the floating gate 221b of the aforementioned first and second embodiments, that is, the processes shown in the aforementioned FIGS. 17 and 18, the gate oxide film 211 exposed in the region between the adjacent control gates 222a is removed using the control gate 222a and the floating gate 221b as a mask to expose the substrate 200 underneath thereof as shown in FIGS. 28A, 28B, and 28C, and then a recess 260 is formed thereon.

As a result, in the case when the distance between the adjacent assist gates 223a becomes smaller, a leakage current at the surface of the substrate in the aforementioned region can be controlled while programming and reading. Therefore, the dimension in the first direction of the assist gate 223a is made greater, and the resistivity of the inversion layer can be decreased without an increase in the leakage current between the source and the drain.

Thus, in this embodiment, since the gate width (WG3) of the assist gate 223a can be made greater than the memory cell of the aforementioned first and second embodiments, an improvement in the programming speed by an increase in the boost voltage (Vboost) and an improvement in the reading speed by a decrease in the resistance of the inversion layer can be designed.

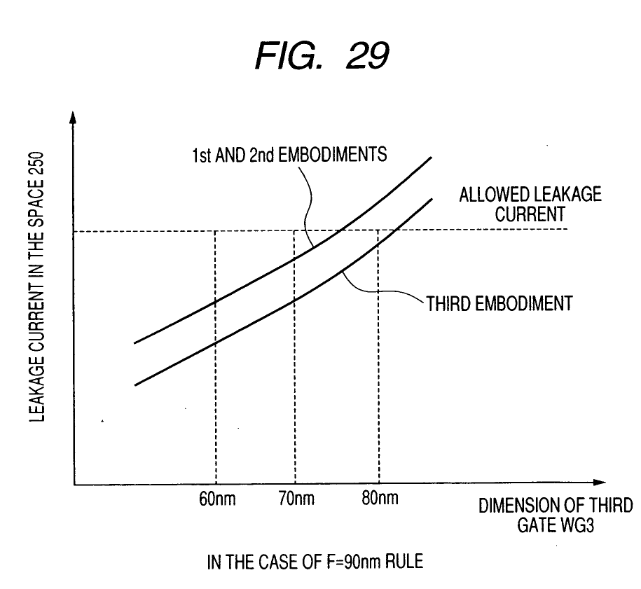

FIG. 29 is a drawing in which the gate width (WG3) dependence of the leakage current between the source and the drain in each of the memory cells of this embodiment and the memory cells of the aforementioned first and second embodiments is compared. As shown the figure, in the memory cell of this embodiment, it is understood that the leakage current between the source and the drain is controlled up to a greater gate width (WG3).

This invention is not limited to the above-mentioned embodiments although the invention having been performed by this inventor was concretely described on the basis of the embodiments, and it goes without saying that a variety of modifications are possible within a range in which there is no departure from the essential points.

A non-volatile semiconductor memory device of the present invention is suitable for a memory device used in personal digital assistants such as a mobile personal computer and a digital still camera.

What is claimed is:

1. A non-volatile semiconductor storage device comprising:
a plurality of first gates formed on the main surface of a semiconductor substrate through a first insulator film,
a plurality of second gates electrically separated from said first gate through a second insulator film covering said first gate, and lying in a first direction of the main surface of said semiconductor substrate,
a plurality of third gates formed on the main surface of said semiconductor substrate through a third insulator film, electrically separated from said first gate through a fourth insulator film, electrically separated from said second film through said second insulator film, and lying in a second direction intersecting said first direction,
wherein an inversion layer formed on the surface of said semiconductor substrate underneath said third gate is used for a local data line when a voltage is applied to said third gate, and
the dimension of said third gate in said first direction on said third insulator film is 10% or greater than the dimension of said first gate lying in said first direction on said first insulator film.

2. A non-volatile semiconductor storage device according to claim 1, wherein
the film thickness of said third insulator film is thinner than the film thickness of said first insulator film.

3. A non-volatile semiconductor storage device according to claim 1, wherein
a channel dopant concentration underneath said third gate is lower than a channel dopant concentration underneath said first gate.

4. A non-volatile semiconductor storage device according to claim 1, wherein
a transistor constituting peripheral circuits is further formed on the main surface of said semiconductor substrate and the film thickness of said third insulator film is thinner than the film thickness of a gate insulator film of a transistor constituting said peripheral circuits.

5. A non-volatile semiconductor storage device according to claim 4, wherein
a gate of the transistor constituting said peripheral circuits is composed of a conductive film which is the same layer as said third gate.

6. A non-volatile semiconductor storage device according to claim 1, wherein
the height of the surface of said semiconductor substrate underneath said first gate is lower than the height of the surface of said semiconductor substrate underneath said third gate and higher than the height of the surface of said semiconductor substrate in a region without said first gate within a space region of said mutually adjacent third gate.

7. A manufacturing method of a non-volatile semiconductor storage device comprising:
(a) a process for forming a plurality of third gates lying in a second direction of the main surface of said semiconductor substrate by patterning a first conductive film formed on said third insulator film after forming a third insulator film on the main surface of a semiconductor substrate,
(b) a process for forming a first insulator film on the surface of said semiconductor substrate in the space region of said mutually adjacent third gates after forming a fourth insulator film on the sidewall of said third gate,
(c) a process for forming a plurality of second conductive layers lying in said second direction on said first insulator film and electrically separated from said third gate through said fourth film,
(d) a process for forming a third conductive layer on said second insulator film after forming a second insulator film covering said third gate and said second conductive film,
(e) a process for forming a plurality of second gates constituting said third conductive film, electrically separated from said third gate through said second insulator film, and lying in a first direction of the main surface of said semiconductor substrate, and a process for forming a first gate constituting said second conductive film, electrically separated from said second gate through said second insulator film, and electrically separated from said third gate through said fourth insulator film, by patterning said third conductive film, said second insulator film, and said second conductive film,
wherein an inversion layer formed on the surface of said semiconductor substrate underneath said third gate is used for a local data line when a voltage is biased to said third gate, and
the dimension of said third gate in said first direction on said third insulator film is 10% or greater than the dimension of said first gate in said first direction on said first insulator film.

8. A manufacturing method of a non-volatile semiconductor storage device according to claim 7, wherein
the film thickness of said third insulator film is made thinner than the film thickness of said first insulator film.

9. A manufacturing method of a non-volatile semiconductor storage device according to claim 7, wherein
a channel dopant concentration underneath said third gate is lower than a channel dopant concentration underneath said first gate.

10. A manufacturing method of a non-volatile semiconductor storage device according to claim 7, further comprising:
(f) a process for forming a first transistor having a first gate insulator film and a second transistor having a second gate insulator film in which the film thickness is greater than the film thickness of said first gate insulator film in a peripheral circuit region of the main surface of said semiconductor substrate,
wherein said process (f) includes
(f1) a process for forming said second gate insulator film in the main surface of said semiconductor substrate,
(f2) a process for forming said first gate insulator film in a memory array region and in a region where said first transistor is formed after removing said second gate insulator film in the memory array region and on the region where said first transistor is formed,
(f3) a process for forming said third insulator film in said memory array region after removing said first gate insulator film in said memory array region.

11. A manufacturing method of a non-volatile semiconductor storage device according to claim 10, wherein
said first transistor gate electrode and said second transistor gate electrode are formed by patterning said first conductive film in said peripheral circuit region when said third gate is formed by patterning said first conductive film.

12. A manufacturing method of a non-volatile semiconductor storage device according to claim 7, wherein
the height of the surface of said semiconductor substrate underneath said first gate is lower than the height of the surface of said semiconductor substrate underneath said third gate and higher than the height of the surface of said semiconductor substrate in a region without said first gate in a space region of said mutually adjacent third gate.
